(19) United States
(12) Patent Application Publication
(10) Pub. No.: US 2026/0323947 A1
(43) Pub. Date: Oct. 15, 2026

(54) INTERLAYER INSULATING LAYER FOR IMPROVING STRUCTURAL STABILITY IN THREE-DIMENSIONAL FLASH MEMORY

(71) Applicant: IUCF-HYU (Industry-University Cooperation Foundation Hanyang University), Seoul (KR)

(72) Inventor: Yun Heub SONG, Seoul (KR)

(73) Assignee: IUCF-HYU (Industry-University Cooperation Foundation Hanyang University), Seoul (KR)

(21) Appl. No.: 19/644,838

(22) Filed: Apr. 10, 2026

(30) Foreign Application Priority Data
Apr. 15, 2025 (KR) 10-2025-0049123
Mar. 5, 2026 (KR) 10-2026-0040024

(51) Int. Cl. H10B 43/35; H10B 43/27; H10B 51/20; H10B 51/30

(52) U.S. Cl. CPC H10B 43/35; H10B 43/27; H10B 51/20; H10B 51/30

(57) ABSTRACT

Disclosed are an interlayer insulating layer for preventing structural deformation caused by a sacrificial layer removal process in a three-dimensional flash memory, a three-dimensional flash memory including the same, and a method of manufacturing the same. According to an embodiment, the interlayer insulating layers may be formed of an insulating material having a Young's modulus with a value that prevents sagging, collapse, or deformation that may occur during a sacrificial layer removal process.

### CROSS-REFERENCE TO RELATED APPLICATIONS

This application claims benefit of priority to both Korean Application No. 10-2025-0049123, filed Apr. 15, 2025, and Korean Application No. 10-2026-0040024, filed on Mar. 5, 2026, each of which is hereby incorporated by reference in its entirety.

### TECHNICAL FIELD

Embodiments relate to an interlayer insulating layer for improving structural stability in a three-dimensional flash memory.

### BACKGROUND ART

A flash memory device is an electrically erasable programmable read-only memory (EEPROM) in which data input and output are electrically controlled by Fowler-Nordheim (F-N) tunneling or hot electron injection so that electrical programming and erasing are enabled, and the flash memory device may be commonly used in computers, digital cameras, MP3 players, game systems, memory sticks, and the like.

In order to increase integration density to meet consumer demand for high performance and low cost, a three-dimensional structure has been proposed in which memory cell transistors are arranged in a vertical direction to form a cell string.

Such a three-dimensional flash memory has a structure in which a plurality of gate electrodes and interlayer insulating layers are alternately stacked in a vertical direction, and memory cells may be formed through a vertical channel structure in regions corresponding to the respective gate electrodes. In general, such a structure may be formed through a gate replacement process, and may be implemented by stacking sacrificial layers, removing the sacrificial layers, and forming the gate electrodes in spaces from which the sacrificial layers have been removed.

However, if the interlayer insulating layers do not have sufficient mechanical strength during the removal process of the sacrificial layers for forming the gate electrodes, structural sagging, collapse, or deformation may occur, the gate electrodes may be formed in non-uniform shapes, or process defects such as open circuits, bridging, or misalignment may occur. Such structural instability may lead to degradation of electrical characteristics of the memory cells, degradation of operating reliability, and reduction in the device yield.

In particular, as the number of stacked memory cells increases, an aspect ratio of the overall structure increases, and a mechanical stress applied to the interlayer insulating layers also increases. Accordingly, it becomes increasingly important to ensure that the interlayer insulating layers have material properties capable of maintaining structural stability during the removal process of the sacrificial layers.

Therefore, there is a need for an interlayer insulating layer structure capable of effectively preventing structural sagging or collapse during the removal process of sacrificial layers and the process of forming gate electrodes, and improving structural stability and manufacturing reliability in the three-dimensional flash memory.

### SUMMARY OF THE INVENTION

### Technical Problem

To improve the structural stability and manufacturing reliability of a three-dimensional flash memory, embodiments provide interlayer insulating layers formed of an insulating material having a Young's modulus with a value that prevents sagging, collapse, or deformation that may occur during a removal process of sacrificial layers.

However, the technical problems to be solved by the present invention are not limited to the foregoing, and may be extended in various ways without departing from the spirit and scope of the present invention.

### Solution to Problem

According to an embodiment, in interlayer insulating layers used in a three-dimensional flash memory, the interlayer insulating layers, while being interposed alternately between gate electrodes, are formed of an insulating material having a Young's modulus with a value that prevents sagging, collapse, or deformation caused by a removal process of sacrificial layers for forming the gate electrodes.

According to an aspect, the interlayer insulating layers may be formed of the insulating material having a Young's modulus greater than that of silicon dioxide (SiO₂).

According to another embodiment, the interlayer insulating layers may be formed of the insulating material having a Young's modulus of 150 GPa or greater.

According to still another embodiment, the interlayer insulating layers may be formed of the insulating material including at least one of silicon oxycarbide (SiOC), silicon oxynitride (SiON), and silicon carbonitride (SiCN).

According to still another embodiment, the insulating material may have a dielectric constant lower than that of the silicon dioxide (SiO₂).

According to still another embodiment, the insulating material may have an etch rate lower than that of the sacrificial layers during the removal process of the sacrificial layers.

According to still another embodiment, the insulating material may have a dielectric breakdown voltage higher than that of the silicon dioxide (SiO₂).

According to still another embodiment, the insulating material may be configured to reduce a structural stress caused by a difference in a coefficient of thermal expansion between the insulating material and the gate electrodes.

According to an embodiment, a three-dimensional flash memory may include: interlayer insulating layers and gate electrodes extending in a horizontal direction and alternately stacked in a vertical direction; and vertical channel structures penetrating the interlayer insulating layers and the gate electrodes and extending in the vertical direction, each of the vertical channel structures including a vertical channel pattern extending in the vertical direction and a data storage pattern formed in contact with an outer sidewall of the vertical channel pattern, wherein the interlayer insulating layers, while being interposed alternately between gate electrodes, are formed of an insulating material having a Young's modulus with a value that prevents sagging, collapse, or deformation caused by a removal process of sacrificial layers for forming the gate electrodes.

According to an embodiment, a method for manufacturing a three-dimensional flash memory may include: preparing a semiconductor structure by forming interlayer insulating layers and sacrificial layers extending in a horizontal direction and alternately stacked in a vertical direction, wherein the interlayer insulating layers are formed of an insulating material having a Young's modulus with a value that prevents sagging, collapse, or deformation caused by a removal process of sacrificial layers for forming gate electrodes; forming channel holes penetrating the semiconductor structure in the vertical direction; forming vertical channel structures extending in the vertical direction in the channel holes, each of the vertical channel structures including a vertical channel pattern extending in the vertical direction and a data storage pattern formed in contact with an outer sidewall of the vertical channel pattern; and removing the sacrificial layers and forming the gate electrodes in spaces from which the sacrificial layers have been removed.

### Advantageous Effects of Invention

Embodiments may improve the structural stability and manufacturing reliability of the three-dimensional flash memory by providing the interlayer insulating layers formed of the insulating material having a Young's modulus with a value that prevents sagging, collapse, or deformation that may occur during the removal process of sacrificial layers.

However, the advantageous effects of the present invention are not limited to the foregoing, and may be variously extended without departing from the spirit and scope of the present invention.

### BRIEF DESCRIPTION OF DRAWINGS

FIG. 1 is a cross-sectional view illustrating a structure of a three-dimensional flash memory according to an embodiment.

FIG. 2 is a graph illustrating characteristics of interlayer insulating layers used in a three-dimensional flash memory according to an embodiment.

FIG. 3 is a flowchart illustrating a method for manufacturing a three-dimensional flash memory according to an embodiment.

### DETAILED DESCRIPTION

Hereinafter, embodiments of the present invention will be described in detail with reference to the accompanying drawings. However, the present invention is not limited or restricted by the embodiments. In addition, the same reference numerals presented in each drawing denote the same elements.

In addition, the terminology used in this specification are terms used to appropriately express preferred embodiments of the present invention, and these may vary according to the intention of a viewer, an operator, or a custom in the field to which the present invention belongs. Therefore, the definitions for these terms should be made based on the contents throughout this specification. For example, in this specification, the singular form also includes the plural form unless specifically mentioned in the phrase. In addition, “comprises” and/or “comprising” used in this specification do not preclude the presence or addition of one or more other components, steps, operations, and/or elements. In addition, although terms such as first, second, and the like are used in this specification to describe various regions, directions, shapes, and the like, these regions, directions, and shapes should not be limited by such terms. These terms are merely used only to distinguish a certain region, direction, or shape from another region, direction, or shape. Therefore, a portion referred to as a first portion in one embodiment may also be referred to as a second portion in another embodiment.

Also, it should be understood that various embodiments of the present invention are different from each other but do not need to be mutually exclusive. For example, specific shapes, structures, and characteristics described here may be implemented in other embodiments in relation to one embodiment without departing from the technical spirit and scope of the present invention. In addition, it should be understood that the position, arrangement, or configuration of individual components in each presented category of embodiments may be changed without departing from the technical spirit and scope of the present invention.

Hereinafter, with reference to the drawings, embodiments will describe in detail interlayer insulating layers formed of an insulating material having a Young's modulus with a value that prevents sagging, collapse, or deformation that may occur during a removal process of sacrificial layers, in order to improve structural stability and manufacturing reliability of a three-dimensional flash memory.

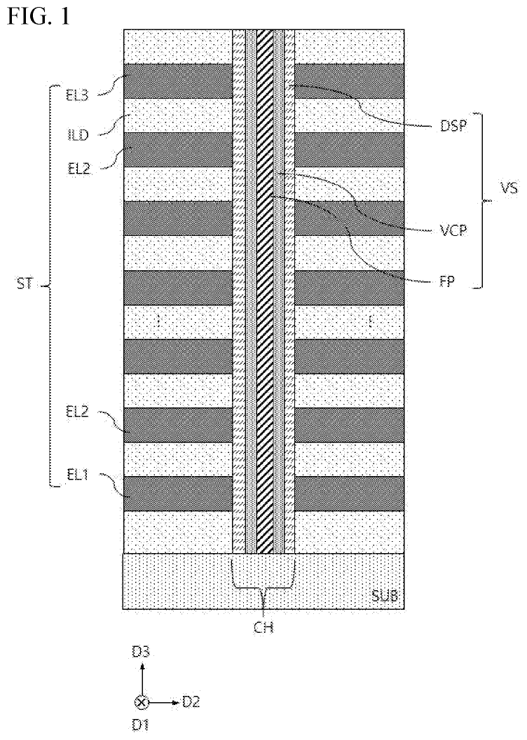

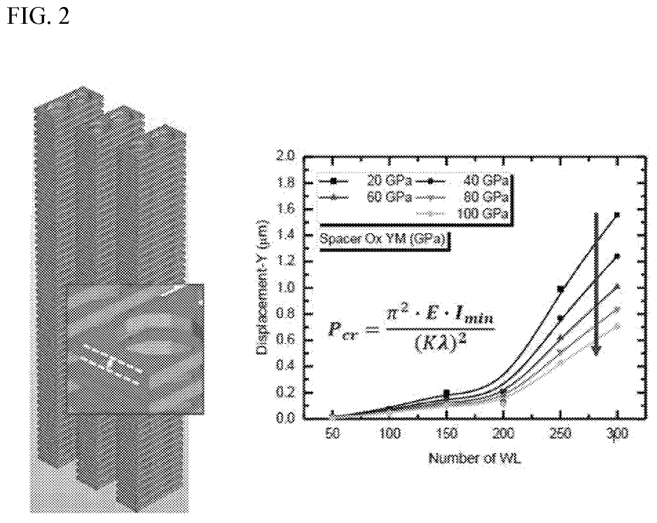

FIG. 1 is a cross-sectional view illustrating a structure of a three-dimensional flash memory according to an embodiment, and FIG. 2 is a graph for explaining characteristics of interlayer insulating layers used in a three-dimensional flash memory according to an embodiment.

Referring to FIG. 1, the substrate (SUB) may be a semiconductor substrate such as a silicon substrate, a silicon-germanium substrate, a germanium substrate, or a monocrystalline epitaxial layer grown on a monocrystalline silicon substrate. The substrate (SUB) may be doped with first conductivity-type impurities (for example, P-type impurities).

Stacked structures (ST) may be disposed on the substrate (SUB). The stacked structures (ST) may be two-dimensionally arranged along a second direction (D2) while being formed to extend in a first direction (D1). In addition, the stacked structures (ST) may be spaced apart from each other in the second direction (D2).

Each of the stacked structures (ST) may include gate electrodes (EL1, EL2, EL3) and interlayer insulating layers (ILD) alternately stacked in a vertical direction (for example, a third direction (D3)) perpendicular to a top surface of the substrate (SUB). The stacked structures (ST) may have a substantially flat top surface. That is, the top surface of the stacked structures (ST) may be parallel to the top surface of the substrate (SUB). Hereinafter, the vertical direction refers to the third direction (D3) or the opposite direction of the third direction (D3).

Each of the gate electrodes (EL1, EL2, EL3) may be one of an erase control line, ground select lines, word lines, or string select lines stacked in sequence on the substrate (SUB).

Each of the gate electrodes (EL1, EL2, EL3) may have a thickness in a third direction (D3) that is substantially the same while being formed to extend in a first direction (D1). Hereinafter, the thickness refers to the thickness in the third direction (D3). Each of the gate electrodes (EL1, EL2, EL3) may be formed of a conductive material. For example, each of the gate electrodes (EL1, EL2, EL3) may include at least one selected from a doped semiconductor (ex, doped silicon etc.), a metal (ex, W (tungsten), Cu (copper), Al (aluminum), Ti (titanium), Ta (tantalum), Mo (molybdenum), Ru (ruthenium), Au (gold) etc.), or a conductive metal nitride (ex, titanium nitride, tantalum nitride etc.). Each of the gate electrodes (EL1, EL2, EL3) may include at least one among all metal materials formable by ALD, in addition to the described metal materials.

More specifically, the gate electrodes (EL1, EL2, EL3) may include a lowermost first gate electrode (EL1), an uppermost third gate electrode (EL3), and a plurality of second gate electrodes (EL2) between the first gate electrode (EL1) and the third gate electrode (EL3). Although the first gate electrode (EL1) and the third gate electrode (EL3) are each illustrated and described in the singular, this is exemplary and is not limited thereto, and according to necessity, the first gate electrode (EL1) and the third gate electrode (EL3) may also be provided in plurality. The first gate electrode (EL1) may correspond to ground select lines. The second gate electrode (EL2) may correspond to word lines. The third gate electrode (EL3) may correspond to string select lines.

Although not shown, an end portion of each of the stacked structures (ST) may have a stepwise structure along a first direction (D1). More specifically, the gate electrodes (EL1, EL2, EL3) of the stacked structures (ST) may have lengths in the first direction (D1) that decrease as they become farther from the substrate (SUB). The third gate electrode (EL3) may have the smallest length in the first direction (D1), and a distance spaced apart from the substrate (SUB) in a third direction (D3) may be the largest. The first gate electrode (EL1) may have the largest length in the first direction (D1), and a distance spaced apart from the substrate (SUB) in the third direction (D3) may be the smallest. By the stepwise structure, each of the stacked structures (ST) may decrease in thickness as it becomes farther from the outer-most one among vertical channel structures (VS) described later, and sidewalls of the gate electrodes (EL1, EL2, EL3) may be spaced apart at regular intervals along the first direction (D1) in a plan view.

Each of the interlayer insulating layers (ILD) may have different thicknesses. As an example, the lowermost one and the uppermost one among the interlayer insulating layers (ILD) may have a thickness smaller than other interlayer insulating layers (ILD). However, this is exemplary and is not limited thereto, and the thickness of each of the interlayer insulating layers (ILD) may have different thicknesses according to characteristics of a semiconductor device, or may be all set the same. As for the interlayer insulating layers (ILD), they may be formed of an insulating material for insulation between the gate electrodes (EL1, EL2, EL3).

In a three-dimensional flash memory in which the number of stacked layers is increased, as an aspect ratio increases, mechanical stress applied to the interlayer insulating layers (ILD) may be increased. Accordingly, when a three-dimensional flash memory is manufactured based on a gate replacement process, conditions capable of maintaining structural stability of the interlayer insulating layers (ILD) during the process are required.

Thus, in one embodiment, the interlayer insulating layers (ILD) may be formed of an insulating material having a Young's modulus with a value that prevents sagging, collapse, or deformation caused by a removal process of sacrificial layers (SAC) for forming the gate electrodes (EL).

More specifically, the interlayer insulating layers (ILD) may be formed of an insulating material having a Young's modulus greater than that of silicon dioxide (SiO₂) used as an interlayer insulating layer in conventional three-dimensional flash memory.

For example, the interlayer insulating layers (ILD) may be formed of an insulating material having a Young's modulus higher than 60 to 75 GPa that silicon dioxide (SiO₂) has, for example, 150 GPa.

As shown in FIG. 2, as the Young's modulus of the interlayer insulating layer increases, a characteristic in which the displacement of the structure decreases may appear under the same gate electrode (EL) (word line (WL)) stacked count condition. For example, compared to a case in which an insulating material having a Young's modulus of about a 20 GPa level is applied, a characteristic in which the displacement of the structure is significantly reduced may appear under the same word-line stacked count condition when an insulating material having a Young's modulus of about 60 GPa, 80 GPa, or 100 GPa or greater is applied.

In particular, in a highly stacked structure in which the number of stacked word lines increases to about 200 layers to 300 layers or more, as shown in the drawings, displacement of the structure increases sharply in a case in which an insulating material having a low Young's modulus is applied, whereas an increase in displacement of the structure may be effectively suppressed in a case in which an insulating material having a high Young's modulus is applied. This is because, as the Young's modulus increases, the stiffness of the structure increases, and accordingly, resistance to mechanical stress and buckling occurring during the process increases.

Therefore, by the interlayer insulating layers (ILD) being formed of an insulating material having a Young's modulus higher than silicon oxide (SiO₂), sagging, collapse, or deformation of the interlayer insulating layers (ILD) that may occur by removal of sacrificial layers (SAC) during a gate replacement process may be effectively suppressed, and structural stability and process reliability of a three-dimensional flash memory having a high-stack structure may be improved.

More specifically, the interlayer insulating layers (ILD) may be formed of an insulating material including at least one among silicon oxycarbide (SiOC), silicon oxynitride (SiON), or silicon carbonitride (SiCN).

In addition, the interlayer insulating layers (ILD) may be configured to simultaneously satisfy not only structural stability but also electrical characteristics and process selectivity.

For example, an insulating material forming the interlayer insulating layers (ILD) may be formed of a material having a relative dielectric constant lower than silicon dioxide (SiO₂). Generally, silicon oxide has a dielectric constant of about a 3.9 level, and by the interlayer insulating layers (ILD) being formed of an insulating material having a lower dielectric constant compared to this, it may reduce parasitic capacitance between the adjacent gate electrodes (EL) and suppress inter-cell interference. More specifically, the interlayer insulating layers (ILD) may be formed of an insulating material having a dielectric constant in a range of about 2.5 to 3.5, for example, it may be formed of an insulating material including silicon oxycarbide (SiOC), carbon-doped silicon oxide, or a porous low-k dielectric material.

As another example, the insulating material forming the interlayer insulating layers (ILD) may be configured to have a high etch selectivity with respect to a removal process of the sacrificial layers (SAC) performed in a gate replacement process. That is, the insulating material may be formed to have a lower etch rate compared to the sacrificial layers (SAC), and accordingly, damage to or a thickness reduction of the interlayer insulating layers (ILD) during a removal process of sacrificial layers may be effectively prevented. More specifically, when the sacrificial layers (SAC) are formed to include polysilicon and a wet etching or dry etching process is applied to removal of the sacrificial layers (SAC), the insulating material forming the interlayer insulating layers (ILD) may be configured to have a characteristic in which an etch rate is low at a level of about 0.1 times to 0.8 times compared to the polysilicon. For example, the insulating material may be formed of an insulating material including silicon nitride (Si₃N₄), silicon oxynitride (SiON), silicon carbonitride (SiCN), or silicon oxycarbide (SiOC).

As another example, an insulating material forming the interlayer insulating layers (ILD) may be configured to have a higher dielectric breakdown voltage than silicon dioxide (SiO₂). Generally, silicon oxide has a dielectric breakdown field at a level of about 8 MV/cm to 12 MV/cm, whereas the insulating material forming the interlayer insulating layers (ILD) according to an embodiment may be a material having a higher dielectric breakdown field than this, for example, a dielectric breakdown field in a range of about 10 MV/cm to 18 MV/cm. Accordingly, stable insulating characteristics may be maintained even under conditions of an electric field concentration increasing according to an increase in the number of stacked layers, and may improve cell reliability and long-term data retention characteristics. For example, the insulating material may be formed of an insulating material including silicon nitride (Si₃N₄), silicon carbonitride (SiCN), silicon oxynitride (SiON), or aluminum oxide (Al₂O₃).

As another example, an insulating material forming the interlayer insulating layers (ILD) may be configured to reduce structural thermal stress caused by a difference in coefficient of thermal expansion (CTE) with the gate electrodes (EL). More specifically, when the gate electrodes (EL) include a metal material, such as tungsten (W), molybdenum (Mo), or titanium nitride (TiN), the insulating material forming the interlayer insulating layers (ILD) may be selected such that a difference in coefficient of thermal expansion with the metal materials is minimized. In one example, the interlayer insulating layers (ILD) may be formed of an insulating material including silicon nitride (Si₃N₄), silicon carbonitride (SiCN), silicon oxynitride (SiON), or aluminum oxide (Al₂O₃) having a coefficient of thermal expansion in a range of about 2 ppm/K to 6 ppm/K. Accordingly, occurrence of interfacial stress, delamination, or a crack occurring during a thermal process may be suppressed.

As such, by the interlayer insulating layers (ILD) being formed of an insulating material that simultaneously satisfies a high Young's modulus, a low dielectric constant, excellent etch selectivity, a high dielectric breakdown voltage, and a characteristic of mitigating a difference in coefficient of thermal expansion with the gate electrodes, structural stability may be ensured during a gate replacement process, and electrical characteristics and reliability of a three-dimensional flash memory having a high-stack structure may be improved.

A plurality of channel holes (CH) penetrating the stacked structures (ST) and a portion of the substrate (SUB) may be provided. Vertical channel structures (VS) may be provided in the channel holes (CH). The vertical channel structures (VS) may be formed to extend in a third direction (D3) as cell strings (CSTR) while being connected to the substrate (SUB). The connection of the vertical channel structures (VS) to the substrate (SUB) may be achieved by bottom surfaces of the vertical channel structures (VS) contacting a top surface of the substrate (SUB), but is not limited thereto, and may be achieved by a portion of each of the vertical channel structures (VS) being embedded in the substrate (SUB). In a case in which a portion of each of the vertical channel structures (VS) is embedded in the substrate (SUB), the bottom surfaces of the vertical channel structures (VS) may be located at a level lower than the top surface of the substrate (SUB).

A plurality of columns of the vertical channel structures (VS) penetrating one of the stacked structures (ST) may be provided. For example, two columns of the vertical channel structures (VS) may penetrate one of the stacked structures (ST). However, it is not limited thereto, and three or more columns of the vertical channel structures (VS) may penetrate one of the stacked structures (ST). In a pair of adjacent columns, the vertical channel structures (VS) corresponding to one column may be shifted in the first direction (D1) from the vertical channel structures (VS) corresponding to an adjacent column. In a plan view, the vertical channel structures (VS) may be arranged in a zigzag pattern along the first direction (D1). However, it is not limited thereto, and the vertical channel structures (VS) may also form an arrangement in which they are aligned in rows and columns.

Each of the vertical channel structures (VS) may be formed to extend from the substrate (SUB) in the third direction (D3). Although each of the vertical channel structures (VS) is illustrated in the drawings as having a pillar shape having the same width at an upper end and a lower end, it is not limited thereto, and may have a shape in which widths in the first direction (D1) and the second direction (D2) increase toward the third direction (D3). This is due to a limitation that, when the channel holes (CH) are etched, the widths in the first direction (D1) and the second direction (D2) decrease toward a direction opposite to the third direction (D3). An upper surface of each of the vertical channel structures (VS) may have a circular shape, an elliptical shape, a square shape, or a bar shape.

Each of the vertical channel structures (VS) may include a data storage pattern (DSP), a vertical channel pattern (VCP), a vertical filling pattern (FP), and a conductive pad (not shown). In each of the vertical channel structures (VS), the vertical channel pattern (VCP) may have a pipe shape closed at a lower end or a macaroni shape. The vertical filling pattern (FP) may fill a space surrounded by the vertical channel pattern (VCP) and the conductive pad.

The data storage pattern (DSP) may cover inner sidewalls of each of the channel holes (CH), while inwardly surrounding an outer sidewall of the vertical channel pattern (VCP) and contacting sidewalls of the gate electrodes (EL) on an outer side. Accordingly, regions of the data storage pattern (DSP) corresponding to the second gate electrodes (EL2), together with regions of the vertical channel pattern (VCP) corresponding to the second gate electrodes (EL2), may constitute memory cells in which a memory operation (a program operation, a read operation, or an erase operation) is performed by a voltage applied through the second gate electrodes (EL2). The memory cells correspond to the memory cell transistors (MCT).

To this end, the data storage pattern (DSP) may serve as a data storage element in a three-dimensional vertical-structure memory by trapping charges or holes by a voltage applied through the second gate electrodes (EL2), or by maintaining a state of the charges (for example, a polarization state of the charges). For example, an ONO (tunnel oxide-charge storage nitride-blocking oxide) layer or a ferroelectric layer may be used as the data storage pattern (DSP). Such a data storage pattern (DSP) may represent a binary data value or a multi-valued data value through a change in trapped charges or holes, or may represent a binary data value or a multi-valued data value through a change in a state of the charges.

The vertical channel pattern (VCP) may contact the inner wall of a tunneling film (TP), penetrate the gate electrodes (EL1, EL2, EL3), and be formed to extend in a vertical direction (for example, the third direction (D3)).

The vertical channel pattern (VCP), as a component for transferring charges or holes to the data storage pattern (DSP), may be formed of monocrystalline silicon or polysilicon so as to form a channel or be boosted by an applied voltage. However, it is not limited or restricted thereto, and the vertical channel pattern (VCP) may be formed of an oxide semiconductor material that may block, suppress, or minimize a leakage current. For example, the vertical channel pattern (VCP) may be formed of an oxide semiconductor material including at least one of In, Zn, or Ga, which has excellent leakage current characteristics, or may be formed of a group IV semiconductor material. The vertical channel pattern (VCP) may be formed of a ZnOx-based material including, for example, AZO, ZTO, IZO, ITO, IGZO, or Ag-ZnO. Accordingly, the vertical channel pattern (VCP) may block, suppress, or minimize leakage current to the gate electrodes (EL1, EL2, EL3) or the substrate (SUB), and may improve transistor characteristics (for example, threshold voltage dispersion and a speed of program/read operations) of at least one of the gate electrodes (EL1, EL2, EL3), thereby improving electrical characteristics of a three-dimensional flash memory.

The bottom surface of the vertical channel pattern (VCP) may be in contact with the substrate (SUB), and the upper surface of the vertical channel pattern (VCP) may be located at a higher level than the upper surface of the third gate electrode (EL3), be substantially coplanar with the upper surface of the vertical filling pattern (FP), and be in contact with the bottom surface of the conductive pad.

The vertical channel pattern (VCP) may be provided between the data storage pattern (DSP) and the vertical filling pattern (FP), and may correspond to the second gate electrodes (EL2). Accordingly, the vertical channel pattern (VCP), together with the data storage pattern (DSP) as described above, may constitute memory cells.

The vertical filling pattern (FP) may be surrounded by the vertical channel pattern (VCP). The upper surface of the vertical filling pattern (FP) may be in contact with the conductive pad, and the bottom surface of the vertical filling pattern (FP) may be in contact with the upper surface of an inner lower end of the vertical channel pattern (VCP). The vertical filling pattern (FP) may be spaced apart from the substrate (SUB) in the third direction (D3). In other words, the vertical filling pattern (FP) may be electrically floating with respect to the substrate (SUB).

The vertical filling pattern (FP) may be formed of a material that facilitates diffusion of charges or holes in the vertical channel pattern (VCP). In more detail, the vertical filling pattern (FP) may be formed of a material with excellent charge and hole mobility. For example, the vertical filling pattern (FP) may be formed of a semiconductor material doped with an impurity, an intrinsic semiconductor material in an undoped state, or a polycrystalline semiconductor material. More specifically, the vertical filling pattern (FP) may be formed of polysilicon doped with a first conductivity-type impurity (for example, a P-type impurity) that is the same as that of the substrate (SUB). That is, the vertical filling pattern (FP) may improve electrical characteristics of the three-dimensional flash memory to enhance a speed of memory operation.

These vertical channel structures (VS) may correspond to channels of an erase control transistor, string selection transistors, a ground selection transistor, and memory cell transistors.

A conductive pad (not shown) may be provided on the upper surface of the vertical channel pattern (VCP) and the upper surface of the vertical filling pattern (FP). The conductive pad may be connected to an upper portion of the vertical channel pattern (VCP) and an upper portion of the vertical filling pattern (FP). A sidewall of the conductive pad may be surrounded by the data storage pattern (DSP). The upper surface of the conductive pad may be substantially coplanar with the upper surface of each of the stacked structures (ST) (that is, the upper surface of a topmost one of the interlayer insulating layers (ILD)). The bottom surface of the conductive pad may be located at a lower level than the upper surface of the third gate electrode (EL3). More specifically, the bottom surface of the conductive pad may be located between the upper surface and the bottom surface of the third gate electrode (EL3). That is, at least a portion of the conductive pad may overlap the third gate electrode (EL3) in a horizontal direction.

The conductive pad may be formed of a semiconductor doped with an impurity or a conductive material. For example, the conductive pad may be formed of a semiconductor material doped with an impurity different from that of the vertical filling pattern (FP) (more specifically, an impurity of a second conductivity type (for example, N-type) different from a first conductivity type (for example, P-type) impurity).

The conductive pad may reduce contact resistance between a bit line (not shown), which will be described below, and the vertical channel pattern (VCP) (or the vertical filling pattern (FP)).

As described above, although the vertical channel structures (VS) have been described as having a structure including a conductive pad, it is not limited or restricted thereto, and may have a structure in which the conductive pad is omitted. In this case, as the conductive pad is omitted in the vertical channel structures (VS), the vertical channel pattern (VCP) and the vertical filling pattern (FP) may each be formed to extend in the third direction (D3) such that upper surfaces of the vertical channel pattern (VCP) and the vertical filling pattern (FP) are substantially coplanar with an upper surface of each of the stacked structures (ST) (that is, an upper surface of a topmost one of the interlayer insulating layers (ILD)). In addition, in this case, a bit line contact plug (not shown), which will be described below, may be in direct contact with and electrically connected to the vertical channel pattern (VCP), instead of being indirectly electrically connected to the vertical channel pattern (VCP) through a conductive pad.

In addition, as described above, although the vertical filling pattern (FP) has been described as being included in the vertical channel structures (VS), it is not limited or restricted thereto, and the vertical filling pattern (FP) may be omitted.

For example, although the three-dimensional flash memory having a structure including the vertical filling pattern (FP) has been described, the three-dimensional flash memory may have a structure including a back gate (not shown) while omitting the vertical filling pattern (FP).

In this regard, a back gate further included in each of the vertical channel structures (VS) may fill an internal space of the vertical channel pattern (VCP) and be formed to extend in a vertical direction (for example, the third direction (D3)). Hereinafter, that the back gate fills the internal space of the vertical channel pattern (VCP) means that the back gate is included in the vertical channel pattern (VCP) in a state of being at least partially surrounded by the vertical channel pattern (VCP).

The back gate may be formed to abut while being at least partially surrounded by the vertical channel pattern (VCP) and to apply a voltage to the vertical channel pattern (VCP) for a memory operation. To this end, the back gate may be formed of a conductive material including at least one selected from a doped semiconductor (for example, doped silicon, etc.), a metal (for example, tungsten (W), copper (Cu), aluminum (Al), titanium (Ti), tantalum (Ta), molybdenum (Mo), ruthenium (Ru), gold (Au), etc.), or a conductive metal nitride (for example, titanium nitride, tantalum nitride, etc.). The back gate may include at least one of all metal materials capable of being formed by ALD in addition to the described metal materials.

At this time, the back gate may be formed to extend along the third direction (D3) from a level corresponding to the first gate electrode (EL1) to a level corresponding to the second gate electrode (EL2) within the vertical channel pattern (VCP). That is, the upper surface of the back gate may be located at a higher level than the upper surface of a topmost one of the second gate electrodes (EL2). However, it is not limited or restricted thereto, and the back gate may also be formed to extend along the third direction (D3) to a level corresponding to the third gate electrode (EL3) within the vertical channel pattern (VCP).

Such a back gate is included in each of the vertical channel patterns (VCP) of the cell strings, and the back gates included in each of the vertical channel patterns (VCP) of the cell strings may all be electrically connected in a plane defined by the first direction (D1) and the second direction (D2). That is, the back gate may be commonly connected to the cell strings. In this case, each of the back gates of the cell strings may be collectively controlled such that the same voltage is applied to all of them.

However, it is not limited or restricted thereto, and the back gates included in each of the vertical channel patterns (VCP) of the cell strings may be electrically connected to each other along the first direction (D1). In this case, the back gates of each of the cell strings arranged along the second direction (D2) may be each independently controlled electrically, so that different voltages may be applied thereto, and the back gates of each of the cell strings arranged along the first direction (D1) may be collectively controlled, so that the same voltage may be applied thereto.

In addition, the back gates included in each of the vertical channel patterns (VCP) of the cell strings may have an electrically separated state for each of the vertical channel structures (VS). In this case, each of the back gates of the vertical channel structures (VS) may all be individually controlled.

With an insulating film (not shown) disposed between the back gate and the vertical channel pattern (VCP), the back gate may be prevented from directly contacting the vertical channel pattern (VCP). The insulating film may be formed of an insulating material such as silicon oxide, similarly to the interlayer insulating layers (ILD).

A separation trench (not shown) extending in the first direction (D1) may be provided between the stacked structures (ST) adjacent to each other. A common source region (not shown) may be provided in the substrate (SUB) exposed by the separation trench (TR). The common source region may extend in the first direction (D1) within the substrate (SUB). The common source region may be formed of a semiconductor material doped with impurities of a second conductivity type (for example, N-type impurities). The common source region may refer to a source line.

A common source plug (not shown) may be provided in the separation trench. The common source plug may be connected to the common source region, and an upper surface thereof may be substantially coplanar with the upper surface of each of the stacked structures (ST) (that is, the upper surface of a topmost one of the interlayer insulating layers (ILD)). The common source plug may have a plate shape extending in the first direction (D1) and the third direction (D3). At this time, the common source plug may have a shape in which a width in the second direction (D2) increases toward the third direction (D3).

Insulating spacers (not shown) may be interposed between the common source plug and the stacked structures (ST). The insulating spacers may face each other between the stacked structures (ST) adjacent to each other. For example, the insulating spacers may be formed of silicon dioxide, silicon nitride, silicon oxynitride, or a low-k material having a low dielectric constant.

A capping insulating film (not shown) may be provided on the stacked structures (ST), the vertical channel structures (VS), and the common source plug. The capping insulating film may cover the upper surface of a topmost one of the interlayer insulating layers (ILD), the upper surface of the conductive pad, and the upper surface of the common source plug. The capping insulating film may be formed of an insulating material different from that of the interlayer insulating layers (ILD). A bit line contact plug (not shown) electrically connected to the conductive pad may be provided in the capping insulating film. The bit line contact plug (not shown) may have a shape in which widths in the first direction (D1) and the second direction (D2) increase toward the third direction (D3).

A bit line (not shown) may be provided on the capping insulating film and the bit line contact plug (not shown). The bit line may be formed of a conductive material extending along the second direction (D2), and may be separately provided for respective vertical channel structures (VS), such that a plurality of bit lines are provided. The conductive material forming the bit line may be the same as the conductive material forming each of the gate electrodes (EL1, EL2, EL3) described above.

The bit line may be electrically connected to the vertical channel structures (VS) through a bit line contact plug. Here, that the bit line is connected to the vertical channel structures (VS) may mean that it is connected to a vertical channel pattern (VCP) included in the vertical channel structures (VS).

The three-dimensional flash memory having such a structure may perform a program operation, a read operation, and an erase operation based on a voltage applied to each of the cell strings (CSTR), a voltage applied to a string select line, a voltage applied to each of the word lines, a voltage applied to a ground select line, a voltage applied to a bit line, and a voltage applied to a source line (including a voltage applied to a back gate in a case where the back gate is included). For example, the three-dimensional flash memory may perform a program operation by forming a channel in the vertical channel pattern (VCP) to transfer charges or holes to a data storage pattern (DSP) of a target memory cell based on a voltage applied to each of the cell strings, a voltage applied to a string select line, a voltage applied to each of the word lines, a voltage applied to a ground select line, a voltage applied to a bit line, and a voltage applied to a source line (including a voltage applied to a back gate in a case where the back gate is included).

The interlayer insulating layers (ILD) used in the three-dimensional flash memory of the above-described structure are not limited to the memory structure of the described embodiment, but may be applied to semiconductor memory devices of various structures, and may implement electrical insulation between the adjacent gate electrodes (EL) in a structure in which a plurality of gate electrodes (EL) are stacked, while simultaneously functioning as a structural support structure.

In particular, by being formed to have a higher Young's modulus than silicon dioxide (SiO₂), the interlayer insulating layers (ILD) may improve resistance to mechanical stress occurring in a highly stacked structure and suppress structural deformation, sagging, or collapse, and along with this, by being configured to together have a lower dielectric constant than silicon dioxide (SiO₂), a lower etch rate than the sacrificial layers (SAC) in a removal process of the sacrificial layers (SAC), a higher dielectric breakdown voltage than silicon dioxide (SiO₂), and a characteristic of mitigating structural stress caused by a difference in coefficient of thermal expansion with the gate electrodes (EL), the interlayer insulating layers may function as an insulating structure that simultaneously improves insulation reliability between the gate electrodes (EL), process stability, and structural stability.

Therefore, the interlayer insulating layers (ILD) are not limited to a specific gate (EL) structure or manufacturing process, and may be applied to various three-dimensional memory structures to implement electrical insulation between the gate electrodes (EL) and simultaneously function as an insulating structure that improves mechanical, electrical, thermal, and process stability.

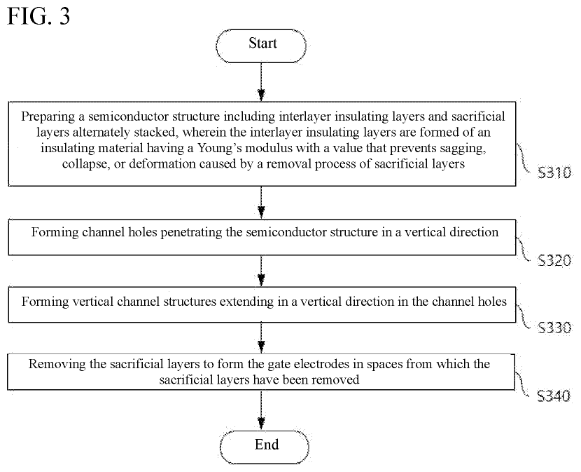

FIG. 3 is a flowchart illustrating a method for manufacturing a three-dimensional flash memory according to an embodiment.

The manufacturing method described below is for manufacturing a three-dimensional flash memory having the structure shown in FIG. 1 based on a gate replacement technique, and is assumed to be performed by an automated and mechanized manufacturing system.

Referring to FIG. 3, in step (S310), the manufacturing system may prepare a semiconductor structure (SEMI-STR) including sacrificial layers (SAC) and interlayer insulating layers (ILD) extending in a horizontal direction (for example, the first direction (D1) and the second direction (D2)) and alternately stacked in a vertical direction.

Here, the interlayer insulating layers (ILD) included in the semiconductor structure (SEMI-STR) may be formed of an insulating material having a Young's modulus with a value that prevents sagging, collapse, or deformation caused by a removal process of sacrificial layers (SAC) for forming gate electrodes (EL).

In more detail, within the semiconductor structure (SEMI-STR), the interlayer insulating layers (ILD), by being formed to have a higher Young's modulus than silicon dioxide (SiO₂), may improve resistance to mechanical stress occurring in a high-stack structure and suppress structural deformation, sagging, or collapse, and along with this, by being configured to together have a lower dielectric constant than silicon dioxide (SiO₂), a lower etch rate than the sacrificial layer (SAC) in a removal process of the sacrificial layer (SAC), a higher dielectric breakdown voltage than silicon dioxide (SiO₂), and a characteristic of mitigating structural stress caused by a difference in thermal expansion coefficient with the gate electrodes (EL), may function as an insulating structure that simultaneously improves insulation reliability between the gate electrodes (EL), process stability, and structural stability.

In step (S320), the manufacturing system may form channel holes (CH) penetrating the semiconductor structure (SEMI-STR) in a vertical direction. In the step (S320) of forming the channel holes (CH), various etching schemes may be utilized.

In step (S330), the manufacturing system may form the vertical channel structures (VS) to extend in the vertical direction within the channel holes (CH).

Step (S330) may include a sub-step of forming a data storage pattern (DSP) on an inner sidewall of each of the channel holes (CH) and a sub-step of forming a vertical channel pattern (VCP) on an inner sidewall of the data storage pattern (DSP), thereby completing formation of the vertical channel structures (VS).

Step (S330) may include forming, by the manufacturing system, components included in the vertical channel structures (VS) described above (for example, a vertical filling pattern (FP), a conductive pad, etc.).

In step (S340), the manufacturing system may, after removing the sacrificial layers (SAC), form the gate electrodes (EL) in spaces from which the sacrificial layers (SAC) have been removed.

Although the method for manufacturing a three-dimensional flash memory having a structure not including a back gate has been described through the above drawings, a three-dimensional flash memory having a structure including a back gate may also be manufactured based on the described steps (S310 to S340). In this case, the back gate may be formed to extend in a vertical direction by filling a conductive material into an internal space of the vertical channel pattern (VCP) in step (S330) in which the vertical channel pattern (VCP) is formed to extend.

Although the embodiments have been described above with reference to the limited embodiments and drawings, those skilled in the art may make various modifications and variations from the above description. For example, appropriate results may be achieved even if the described techniques are performed in an order different from that described, and/or components of the described systems, structures, apparatuses, circuits, etc. are combined or associated in a form different from that described, or are replaced or substituted with other components or equivalents.

Therefore, other implementations, other embodiments, and equivalents to the claims also fall within the scope of the claims to be described below.

1. Interlayer insulating layers used in a three-dimensional flash memory, wherein
the interlayer insulating layers, while being interposed alternately between gate electrodes, are formed of an insulating material having a Young's modulus with a value that prevents sagging, collapse, or deformation caused by a removal process of sacrificial layers for forming the gate electrodes.

2. The interlayer insulating layers of claim 1, wherein
the interlayer insulating layers are formed of the insulating material having a Young's modulus greater than that of silicon dioxide (SiO₂).

3. The interlayer insulating layers of claim 2, wherein
the interlayer insulating layers are formed of the insulating material having a Young's modulus of 150 GPa or greater.

4. The interlayer insulating layers of claim 3, wherein
the interlayer insulating layers are formed of the insulating material comprising at least one of silicon oxycarbide (SiOC), silicon oxynitride (SiON), or silicon carbonitride (SiCN).

5. The interlayer insulating layers of claim 2, wherein
the insulating material has a dielectric constant lower than that of the silicon dioxide (SiO₂).

6. The interlayer insulating layers of claim 2, wherein
the insulating material has an etch rate lower than that of the sacrificial layers during the removal process of the sacrificial layers.

7. The interlayer insulating layers of claim 2, wherein
the insulating material has a dielectric breakdown voltage higher than that of the silicon dioxide (SiO₂).

8. The interlayer insulating layers of claim 2, wherein
the insulating material is configured to reduce structural stress caused by a difference in thermal expansion coefficient with the gate electrodes.

9. A three-dimensional flash memory, comprising:
interlayer insulating layers and gate electrodes extending in a horizontal direction and alternately stacked in a vertical direction; and
vertical channel structures penetrating the interlayer insulating layers and the gate electrodes and extending in the vertical direction, each of the vertical channel structures comprising a vertical channel pattern extending in the vertical direction and a data storage pattern formed in contact with an outer sidewall of the vertical channel pattern,
wherein the interlayer insulating layers, while being interposed alternately between gate electrodes, are formed of an insulating material having a Young's modulus with a value that prevents sagging, collapse, or deformation caused by a removal process of sacrificial layers for forming the gate electrodes.

10. A method for manufacturing a three-dimensional flash memory, comprising:
preparing a semiconductor structure by forming interlayer insulating layers and sacrificial layers extending in a horizontal direction and alternately stacked in a vertical direction, wherein the interlayer insulating layers are formed of an insulating material having a Young's modulus with a value that prevents sagging, collapse, or deformation caused by a removal process of sacrificial layers for forming gate electrodes;
forming channel holes penetrating the semiconductor structure in the vertical direction;
forming vertical channel structures extending in the vertical direction in the channel holes, each of the vertical channel structures comprising a vertical channel pattern extending in the vertical direction and a data storage pattern formed in contact with an outer sidewall of the vertical channel pattern; and
removing the sacrificial layers and forming the gate electrodes in spaces from which the sacrificial layers have been removed.
